(19) United States
(12) Patent Application Publication
(10) Pub. No.: US 2026/0090418 A1
(43) Pub. Date: Mar. 26, 2026

(54) SEMICONDUCTOR PACKAGE INCLUDING A CONDUCTIVE POST

(71) Applicant: SAMSUNG ELECTRONICS CO., LTD., SUWON-SI (KR)

(72) Inventors: HYEONJEONG HWANG, Suwon-si (KR); HYUNSOO CHUNG, Suwon-si (KR)

(21) Appl. No.: 19/211,600

(22) Filed: May 19, 2025

(30) Foreign Application Priority Data
Sep. 25, 2024 (KR) 10-2024-0130118

(51) Int. Cl. H01L 23/498; H01L 21/48; H01L 21/56; H01L 23/00; H01L 23/31; H01L 23/538; H01L 25/10; H01L 25/18; H10B 80/00; H10D 80/30

(52) U.S. Cl. CPC H10W 70/65; H10W 70/611; H10W 70/69; H10W 74/117; H10W 90/00; H10W 90/401; H10B 80/00; H10D 80/30; H10W 42/121; H10W 70/093; H10W 70/60; H10W 74/016; H10W 90/701; H10W 90/722; H10W 90/724

(57) ABSTRACT

A semiconductor package may include a first redistribution substrate, a first semiconductor chip on the first redistribution substrate, a conductive post on the first redistribution substrate and horizontally spaced apart from the first semiconductor chip, the conductive post having protruding portions formed on a side surface thereof, a first mold layer disposed on the first redistribution substrate and a side surface of the first semiconductor chip, and a first interface layer including a vertical portion between the first mold layer and the protruding portions of the conductive post and a horizontal portion extending from a lower end portion of the conductive post.

### CROSS-REFERENCE TO RELATED APPLICATIONS

This application claims priority under 35 U.S.C. § 119 to Korean Patent Application No. 10-2024-0130118, filed on Sep. 25, 2024, in the Korean Intellectual Property Office, the entire contents of which are hereby incorporated by reference.

### BACKGROUND

### 1. Technical Field

The present disclosure relates to a semiconductor package, and more particularly to a semiconductor package including a conductive post.

### 2. Discussion of Related Art

Demand for portable electronic devices has been rapidly increasing. In particular, portable electronic devices having reduced sizes and weights are in demand in the market. To maintain this trend, the electronic components of these portable electronic devices need to have reduced sizes and weights. Further, packaging technologies have been developed that may reduce an overall size and weight of the electronic components by integrating a plurality of individual components in a single package. For a semiconductor package in which a plurality of components are provided, warpage, heat-dissipation, and electric characteristics of the semiconductor package may be obstacles to reducing of the size of the package.

### SUMMARY

An embodiment of the inventive concept provides a semiconductor package with improved reliability and a method of fabricating the same.

According to an embodiment of the inventive concept, a semiconductor package may include a first redistribution substrate, a first semiconductor chip on the first redistribution substrate, a conductive post on the first redistribution substrate and horizontally spaced apart from the first semiconductor chip, the conductive post having protruding portions formed on a side surface thereof, a first mold layer disposed on the first redistribution substrate and a side surface of the first semiconductor chip, and a first interface layer including a vertical portion between the first mold layer and the protruding portions of the conductive post and between the first mold layer and a horizontal portion extending from a lower end portion of the conductive post.

According to an embodiment of the inventive concept, a semiconductor package may include a first redistribution substrate, a semiconductor chip on the first redistribution substrate, a conductive post on the first redistribution substrate and horizontally spaced apart from the semiconductor chip, a mold layer provided on the first redistribution substrate and on a side surface of the semiconductor chip, and a first interface layer between the mold layer and a side surface of the conductive post. The side surface of the conductive post may have a first surface roughness, and a top surface of the conductive post may have a second surface roughness. The second surface roughness is smaller than the first surface roughness.

According to an embodiment of the inventive concept, a semiconductor package include a first redistribution substrate including first insulating layers and first redistribution patterns, which at least partially penetrate the first insulating layers, a semiconductor chip on the first redistribution substrate, a conductive post on the first redistribution substrate and horizontally spaced apart from the semiconductor chip, a side surface of the conductive post defined by protruding portions, a mold layer provided on the first redistribution substrate and a side surface of the semiconductor chip, a first interface layer between the mold layer and the protruding portions of the conductive post and between the mold layer and at least a portion of a top surface of the first redistribution substrate, a second redistribution substrate provided on the mold layer and electrically connected to the conductive post, the second redistribution substrate including second insulating layers and second redistribution patterns, which at least partially penetrate the second insulating layers, and an outer coupling terminal on a bottom surface of the first redistribution substrate. The conductive post electrically connects the first redistribution patterns and the second redistribution patterns to each other.

According to an embodiment of the inventive concept, a method of fabricating a semiconductor package, according to an embodiment of the inventive concept may include: providing a first redistribution substrate including a first redistribution pad; forming a preliminary conductive post on the first redistribution pad of the first redistribution substrate; performing a surface treatment process to increase a surface roughness of the preliminary conductive post; mounting a first semiconductor chip on the first redistribution substrate horizontally spaced apart from the preliminary conductive post; forming a first interface layer on the preliminary conductive post and at least a portion of the first redistribution pad; forming a second interface layer on the first semiconductor chip, wherein the second interface layer is spaced apart from the first interface layer; forming a first mold layer on the first redistribution substrate and on the first semiconductor chip to cover the first interface layer and the second interface layer; removing a portion of the first mold layer and the preliminary conductive post to form a conductive post; and forming a second redistribution substrate on a top surface of the first mold layer and a top surface the conductive post.

According to an embodiment, a method of fabricating a semiconductor package may further include forming a first under-bump pattern on a bottom surface of the first redistribution substrate.

According to an embodiment, a method of fabricating a semiconductor package may further include mounting a second semiconductor chip on the second redistribution substrate, wherein the second semiconductor chip is electrically connected to the conductive post. According to an embodiment, a method of fabricating a semiconductor package may further include forming a second mold layer on the second redistribution substrate and on the second semiconductor chip.

### BRIEF DESCRIPTION OF THE DRAWINGS

FIG. 1 is a plan view illustrating a semiconductor package according to an embodiment of the inventive concept.

FIG. 2A is a sectional view taken along a line A-A′ of FIG. 1.

FIG. 2B is a sectional view illustrating a semiconductor package according to an embodiment of the inventive concept.

FIG. 3 is an enlarged sectional view illustrating a portion ‘P’ of FIG. 2A.

FIGS. 4A, 4B, 4C, 4D, 4E, and 4F, and FIG. 5 are sectional views and an enlarged sectional view illustrating a method of fabricating a semiconductor package, according to an embodiment of the inventive concept.

### DETAILED DESCRIPTION

Example embodiments of the inventive concepts will now be described more fully with reference to the accompanying drawings, in which example embodiments are shown. Embodiments should be understood to include all changes, equivalents, and replacements within the inventive concept and the technical scope of the disclosure. Aspects of the inventive concept may be embodied in different forms and should not be construed as limited to embodiments set forth herein. Rather, embodiments are provided so that this disclosure will be thorough and complete, and will fully convey the scope of the disclosure to those skilled in the art.

In a semiconductor package having stacked chips, a conductive post may be provided to electrically connect an upper chip to an exterior device. The conductive post and a lower chip may be surrounded by a mold layer. In some cases, a metal oxide layer formed on side surfaces of the conductive post facing the mold layer may delaminate to form a void or crevice between the side surfaces of the conductive posts and the metal oxide layer, which may separate the side surfaces of the conductive posts from the mold layer, and which may lead to a defect in the semiconductor package. According to an embodiment of the inventive concept, a semiconductor package may include a conductive post including protruding portions formed on a side surface of the conductive post, and an interface layer provided between a mold layer and the side surface of the conductive post having the protruding portions. The interface layer may attach the mold layer to the conductive posts, and the protruding portions formed on the side surface of the conductive post may be robustly and mechanically connected to the interface layer. Accordingly, it may be possible to inhibit or prevent the mold layer from being delaminated from the conductive posts.

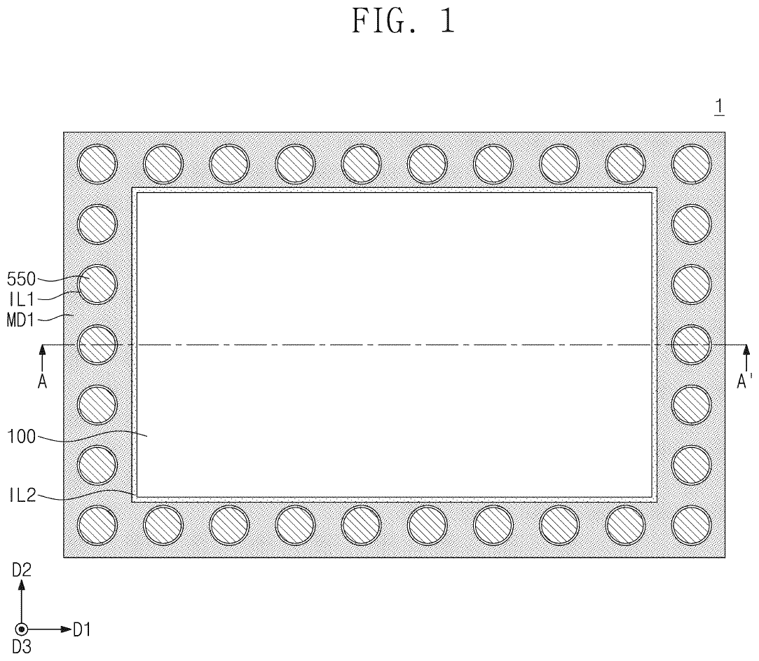

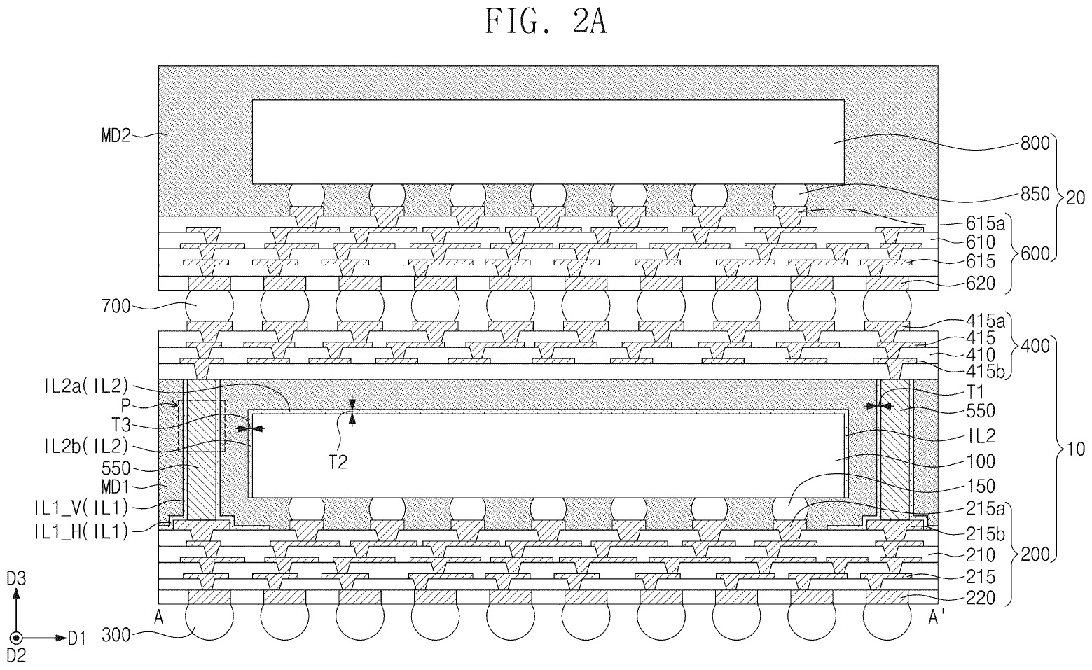

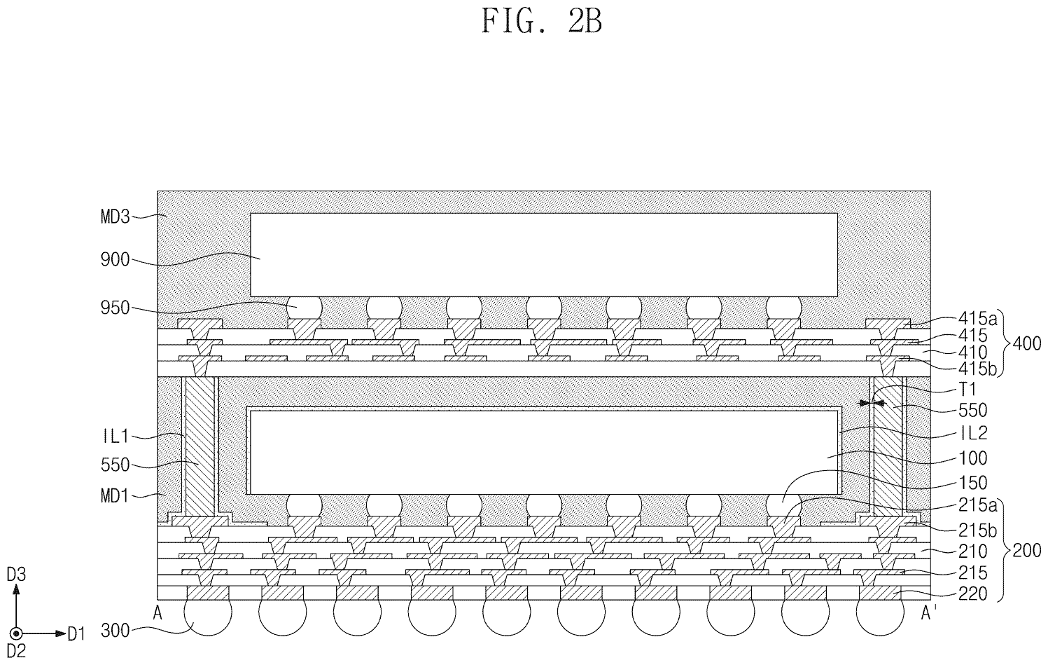

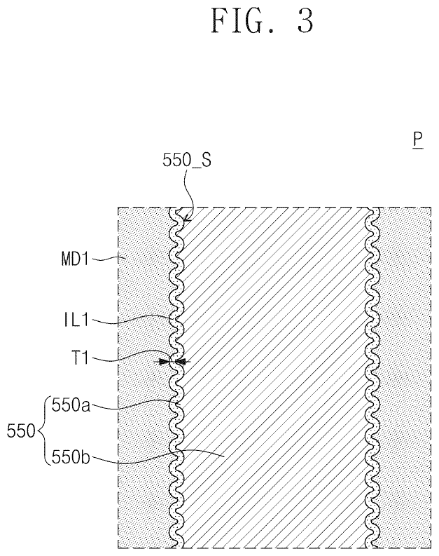

FIG. 1 is a plan view illustrating a semiconductor package according to an embodiment of the inventive concept. FIG. 2A is a sectional view taken along a line A-A′ of FIG. 1. FIG. 3 is an enlarged sectional view illustrating a portion ‘P’ of FIG. 2A.

Referring to FIG. 1 and FIG. 2A, a semiconductor package according to an embodiment of the inventive concept may include a first sub-semiconductor package 10 and a second sub-semiconductor package 20. The second sub-semiconductor package 20 may be disposed on the first sub-semiconductor package 10.

The first sub-semiconductor package 10 may include a first redistribution substrate 200, a first semiconductor chip 100, a first mold layer MD1, a conductive post 550, a first interface layer IL1, and a second redistribution substrate 400.

The first redistribution substrate 200 may include a plurality of first insulating layers 210 and a plurality of first redistribution patterns 215. The plurality of first insulating layers 210 sequentially stacked. The plurality of first redistribution patterns 215 may be disposed on, and penetrate, each first insulating layer of the plurality of first insulating layers 210. In the present specification, a first direction D1 may be parallel to a bottom surface of the first redistribution substrate 200. A second direction D2 may be parallel to the bottom surface of the first redistribution substrate 200 and may be perpendicular to the first direction D1. A third direction D3 may be perpendicular to the bottom surface of the first redistribution substrate 200 and a plane formed by the first direction D1 and the second direction D2.

The first insulating layers 210 may include an organic material (e.g., a photoimageable dielectric (PID) material). The PID material may be a polymer. The PID material may include at least one of photoimageable polyimide, polybenzoxazole, phenol-based polymers, or benzocyclobutene-based polymers. In FIG. 2A and FIG. 2B, the first insulating layers 210 may exhibit an observable interference therebetween, but the inventive concept is not limited to this example. In an embodiment, there may be no observable interface between adjacent ones of the first insulating layers 210.

The first redistribution patterns 215 may be provided in the first insulating layers 210. At least one of the first redistribution patterns 215 may be provided to at least partially penetrate a corresponding one of the first insulating layers 210. The first redistribution patterns 215 may include a first via portion and a first wire portion, which may be connected to each other. The first wire portion may be a portion used for a horizontal interconnection in the first redistribution substrate 200. The first via portion may be a portion disposed in the first insulating layers 210 and which may be used to vertically connect the first redistribution patterns 215 to each other. The first wire portion may be provided on the first via portion. The first wire portion may be connected to the first via portion, without an interface therebetween. The first wire portion of the first redistribution pattern 215 may be disposed on a top surface of the first insulating layer 210. The first via portion of the first redistribution pattern 215 may penetrate the first insulating layer 210. The first via portion of the first redistribution pattern 215 may penetrate the first insulating layer 210 and may be connected the first wire portion of a lower instance of the first redistribution pattern 215 thereunder. The first via portion may extend in the third direction D3. The first via portion may have a tapered structure that is extended in the third direction D3. The first via portion may have an increasing horizontal width in the third direction D3. For example, the first via portion may have an increasing width, as a distance to the first semiconductor chip 100 decreases. The first redistribution patterns 215 may include a conductive material. For example, the first redistribution patterns 215 may be formed of, or include copper (Cu).

Seed patterns may be disposed on bottom surfaces of the first redistribution patterns 215. For example, the seed patterns may be disposed at the bottom and side surfaces of the first via portion of the first redistribution pattern 215 and the bottom surface of the first wire portion of the first redistribution pattern 215. The seed patterns may include a material different from the first redistribution patterns 215. For example, the seed patterns may include copper (Cu), titanium (Ti), or alloys thereof. In an embodiment, the first redistribution patterns 215 may further include a barrier layer. The barrier layer may inhibit or prevent a material in the first redistribution patterns 215 from being diffused. The barrier layer may include titanium nitride (TiN) or tantalum nitride (TaN).

The first redistribution patterns 215 may include first redistribution pads 215a and 215b. For example, the first redistribution pads 215a and 215b may be portions of the first redistribution patterns 215 disposed at an uppermost level of the first redistribution substrate 200. The first redistribution pads 215a and 215b may have protruding top surfaces that extend to a height higher than the uppermost insulating layer of the first insulating layers 210.

First under-bump patterns 220 may be provided on the bottom surface of the first redistribution substrate 200. The first under-bump patterns 220 may be spaced apart from each other. For example, the first under-bump patterns 220 may be spaced apart from each other in the first direction D1 and the second direction D2. The first under-bump patterns 220 may be electrically connected to the first redistribution patterns 215. For example, the first under-bump patterns 220 may be directly connected to the lowermost redistribution patterns of the first redistribution patterns 215. The first under-bump patterns 220 may be electrically connected to the first redistribution pads 215a and 215b through the first redistribution patterns 215. The first under-bump patterns 220 may include a conductive material. For example, the first under-bump patterns 220 may include copper (Cu).

Outer coupling terminals 300 may be provided on bottom surfaces of the first under-bump patterns 220, respectively. The outer coupling terminals 300 may be spaced apart from each other. For example, the outer coupling terminals 300 may be spaced apart from each other in the first direction D1 and the second direction D2. The outer coupling terminals 300 may include a solder material. For example, the outer coupling terminals 300 may include tin (Sn), bismuth (Bi), lead (Pb), or silver (Ag), or alloys thereof.

First connection terminals 150 may be provided on the first redistribution substrate 200. The first connection terminals 150 may be directly connected to the first redistribution pads 215a and may be electrically connected to the first redistribution pattern 215. The first connection terminals 150 may be spaced apart from each other. For example, the first connection terminals 150 may be spaced apart from each other in the first direction D1 and the second direction D2. The first connection terminals 150 may be used to connect the first redistribution substrate 200 to the first semiconductor chip 100. The first connection terminals 150 may include a solder material. For example, the first connection terminals 150 may include tin (Sn), bismuth (Bi), lead (Pb), or silver (Ag), or alloys thereof.

The first semiconductor chip 100 may be disposed on a top surface of the first redistribution substrate 200. The first semiconductor chip 100 may be electrically connected to the first redistribution substrate 200 via the first connection terminals 150. For example, the first semiconductor chip 100 may include chip pads disposed on a bottom surface of the first semiconductor chip 100 can connected to the first connection terminals 150. However, embodiments are not limited thereto, and the first semiconductor chip 100 may be electrically connected to the first redistribution substrate 200 via other connection types. In an embodiment, the first semiconductor chip 100 may include a memory chip or a logic chip. The memory chip may include volatile memory chips (e.g., dynamic random access memory (DRAM) or static random access memory (SRAM) chips) or nonvolatile memory chips (e.g., phase-change random access memory (PRAM), magnetoresistive random access memory (MRAM), ferroelectric random access memory (FeRAM), or resistive random access memory (RRAM) chips). The logic chip may be a micro-processor (e.g., a central processing unit (CPU), a graphics processing unit (GPU), or an application processor (AP)), an analog device, or a digital signal processor.

The first mold layer MD1 may be disposed on the top surface of the first redistribution substrate 200. The first mold layer MD1 may cover the first semiconductor chip 100, on the first redistribution substrate 200. For example, the first mold layer MD1 may be disposed on a top surface and a side surface of the first semiconductor chip 100. In an embodiment, the first mold layer MD1 may be disposed the side surfaces of the first semiconductor chip 100 and may expose the top surface of the first semiconductor chip 100. The first mold layer MD1 may further be disposed between the first semiconductor chip 100 and the top surface of the first redistribution substrate 200, surrounding the first connection terminals 150. For example, the first mold layer MD1 may cover the first semiconductor chip 100 and side surfaces of conductive posts 550. In an embodiment, the first mold layer MD1 may include an epoxy molding compound.

Conductive posts 550 may be disposed on the first redistribution substrate 200. Conductive posts 550 may be horizontally spaced apart from the first semiconductor chip 100. Each of the conductive posts 550 may be provided to penetrate at least a portion of the first mold layer MD1. The conductive posts 550 may be spaced apart from each other in the first and second directions D1 and D2. The conductive posts 550 may be disposed around the first semiconductor chip 100 in a plan view, but the inventive concept is not limited thereto. The conductive posts 550 may electrically connect the first redistribution substrate 200 to the second redistribution substrate 400. The bottom surfaces of the conductive posts 550 may be directly connected to the first redistribution pads 215b. A width of the conductive post 550 may be equal to, or smaller than a width of the first redistribution pad 215b. For example, the conductive post 550 may expose a portion of a top surface of the first redistribution pad 215b. The top surfaces of the conductive posts 550 may be coplanar with a top surface of the first mold layer MD1. In an embodiment, the conductive posts 550 may be formed of, or include copper (Cu).

Referring to FIG. 2A and FIG. 3, each of the conductive posts 550 may include a body portion 550b and protruding portions 550a. The body portion 550b may extend in the third direction D3. The protruding portions 550a may protrude from the body portion 550b. The protruding portion 550a may be a portion of the conductive post 550 protruding from a side surface 550_S of the conductive post 550. FIG. 3 illustrates an example, in which the protruding portion 550a is illustrated to protrude in a direction parallel to the bottom surface of the first redistribution substrate 200 (e.g., in the first direction D1). The protruding portions 550a may protrude to surround the side surface 550_S of the conductive post 550. Although the protruding portions 550a are illustrated to have a uniform size, in an embodiment, the protruding portions 550a may be provided to have a non-uniform size.

The side surface 550_S of the conductive post 550 may have a first surface roughness. In an embodiment, the first surface roughness of the conductive post 550 defining the protruding portions 550a may range from about 0.1 micrometers (μm) to about 2 μm, and in particular from about 0.3 μm to about 1.3 μm. The first surface roughness may be due to the protruding portions 550a formed on the side surface 550_S of the conductive post 550. The terms “about” or “approximately” as used herein are inclusive of the stated value(s) and mean within an acceptable range of deviation for the particular value as determined by one of ordinary skill in the art, considering the measurement in question and the error associated with measurement of the particular quantity (for example, the limitations of the measurement system). In FIG. 3, the side surface 550_S and protruding portions 550a are illustrated as having a regular, repeating surface structure, however embodiments are not limited thereto. For example, the first surface roughness may be irregular, and may vary along the side surface 550_S within may a range from about 0.1 micrometers (μm) to about 2 μm, and in particular from about 0.3 μm to about 1.3 μm.

A top surface of the conductive post 550 may have a second surface roughness. The protruding portions 550a may not be formed on the top surface of the conductive post 550. For example, the top surface of the conductive post 550 may be relatively flat. The second surface roughness of the top surface of the conductive post 550 may be smaller than the first surface roughness of the side surface 550_S of the conductive post 550. In an embodiment, the second surface roughness may range from about 0.001 μm to about 0.1 μm. Each of the first and second surface roughness may be an arithmetic average roughness (Ra), which means an average value of an absolute value of the surface roughness.

The first interface layer IL1 may include a vertical portion IL1_V disposed between interposed between the first mold layer MD1 and the conductive posts 550. More specifically, the first interface layer IL1 may be interposed between the first mold layer MD1 and the side surfaces 550_S of the conductive posts 550. The first interface layer IL1 may cover the protruding portions 550a formed on the side surfaces 550_S.

The protruding portions 550a, which may be formed on the side surfaces 550_S of the conductive posts 550, may increase a contact area between the first interface layer IL1 and the conductive posts 550. In addition, the first interface layer IL1 may fill a space between the protruding portions 550a of the conductive posts 550, and thus, an adhesion strength between the first interface layer IL1 and the conductive posts 550 may be increased. Accordingly, the first interface layer IL1 may not be delaminated from the conductive posts 550 and may be robustly adhered to the conductive posts 550. Furthermore, the first interface layer IL1 may be configured to increase the adhesion strength between the first mold layer MD1 and the conductive posts 550.

The first interface layer IL1 may be disposed on at least a portion of the side surface 550_S of the conductive post 550. The first interface layer IL1 may cover the side surface 550_S of the conductive post 550. The first interface layer IL1 may be extended to cover at least a portion of the top surface of the first redistribution substrate 200. For example, the first interface layer IL1 may include a horizontal portion IL1_H extending to cover the first redistribution pad 215b connected to the conductive post 550, and at least a portion of a top surface of the uppermost insulating layer of the first insulating layer 210. For example, the horizontal portion IL1_H may extend from a lower end portion of the conductive post 550 disposed proximate to the first redistribution pad 215b. The horizontal portion IL1_H of the first interface layer IL1 may cover an exposed portion of the top surface of the first redistribution pad 215b, a side wall of the first redistribution pad 215b, and the top surface of the uppermost insulating layer of the first insulating layer 210. In an embodiment, the horizontal portion IL1_H of the first interface layer IL1 may be overlapped with the first semiconductor chip 100, when viewed in a plan view. In an embodiment, the first interface layer IL1 may include a silicon-based insulating material and may further include copper oxide. In an embodiment, a thickness T1 of the first interface layer IL1 may range from about 1 μm to about 5 μm.

A second interface layer IL2 may be interposed between the first semiconductor chip 100 and the first mold layer MD1. For example, the second interface layer IL2 may be interposed between the side surface of the first semiconductor chip 100 and the first mold layer MD1, and between the top surface of the first semiconductor chip 100 and the first mold layer MD1. That is, the second interface layer IL2 may cover the top and side surfaces of the first semiconductor chip 100. The second interface layer IL2 may not be connected to the first interface layer IL1 and may be spaced apart from the first interface layer IL1. In an embodiment, the horizontal portion IL1_H of the first interface layer IL1 may be overlapped with a portion of the second interface layer IL2, when viewed in a plan view.

The second interface layer IL2 may include a first portion IL2a covering the top surface of the first semiconductor chip 100 and a second portion IL2b covering the side surface of the first semiconductor chip 100. A thickness T2 of the first portion IL2a may be equal to, or greater than a thickness T3 of the second portion IL2b. In an embodiment, the thickness T2 of the first portion IL2a may range from about 1 μm to about 4 μm, and the thickness T3 of the second portion IL2b may range from about 0.5 μm to about 2.5 μm.

The second redistribution substrate 400 may be disposed on the first mold layer MD1. The second redistribution substrate 400 may include a plurality of second insulating layers 410 and a plurality of second redistribution patterns 415. The plurality of second insulating layers 410 may be sequentially stacked. The plurality of second redistribution patterns 415 may be disposed on, and penetrate, each second insulating layer of the plurality of second insulating layers 410. The second insulating layers 410 may be formed of, or include an organic material (e.g., a photoimageable dielectric (PID) material). According to an embodiment, the adhesion of the first interface layer IL1 to the conductive posts 550 may inhibit or prevent the occurrence of a delamination of a structure including the first mold layer MD1, the first interface layer IL1 and the conductive posts 550, and may reduce a potential for cracks to form in the PID material during manufacture of the second redistribution substrate 400.

The second redistribution patterns 415 may be provided in the second insulating layers 410. Each of the second redistribution patterns 415 may be provided to penetrate at least a portion of a corresponding one of the second insulating layers 410. At least one of the second redistribution patterns 415 may include a second via portion and a second wire portion, which may be connected to each other. The second wire portion may be a portion used for a horizontal interconnection in the second redistribution substrate 400. The second via portion may be a portion disposed in the second insulating layers 410 and which may be used to vertically connect the second redistribution patterns 415 to each other. The second wire portion may be provided on the second via portion. The second wire portion may be connected to the second via portion, without an interface therebetween. The second wire portion of the second redistribution pattern 415 may be disposed on a top surface of the second insulating layer 410. The second via portion of the second redistribution pattern 415 may penetrate the second insulating layer 410. The second via portion of the second redistribution pattern 415 may penetrate the second insulating layer 410 and may be connected the second wire portion of a lower instance of the second redistribution pattern 415 thereunder. The second via portion may extend in the third direction D3. The second via portion may have a tapered structure that is extended in the third direction D3. The second via portion may have an increasing horizontal width in the third direction D3. For example, the second via portion may have a decreasing width, as a distance to the first semiconductor chip 100 decreases. The second redistribution pattern 415 may include a conductive material. For example, the second redistribution pattern 415 may be formed of, or include copper (Cu).

Seed patterns may be disposed on bottom surfaces of the second redistribution pattern 415. For example, the seed patterns may be disposed at the bottom and side surfaces of the first via portion of the second redistribution pattern 415 and the bottom surface of the second wire portion of the second redistribution pattern 415. The seed patterns may include a material different from the second redistribution pattern 415. For example, the seed patterns may include copper (Cu), titanium (Ti), or alloys thereof. In an embodiment, the second redistribution pattern 415 may further include a barrier layer. The barrier layer may inhibit or prevent a material in the second redistribution pattern 415 from being diffused. The barrier layer may include titanium nitride (TiN) or tantalum nitride (TaN).

The second redistribution patterns 415 may include second redistribution pads 415a. For example, the second redistribution pads 415a may be portions of the second redistribution patterns 415 disposed at an uppermost level of the second redistribution substrate 400. The second redistribution pads 415a may have protruding top surfaces that extend to a height higher than the uppermost insulating layer of the second insulating layers 410.

The second sub-semiconductor package 20 may be disposed on the first sub-semiconductor package 10. The second sub-semiconductor package 20 may include a third redistribution substrate 600, a second semiconductor chip 800, and a second mold layer MD2.

The third redistribution substrate 600 may include a plurality of third insulating layers 610 and a plurality of third redistribution patterns 615, which may be sequentially stacked. The third insulating layers 610 may include an organic material (e.g., a photoimageable dielectric (PID) material).

The third redistribution patterns 615 may be provided in the third insulating layers 610. Each of the third redistribution patterns 615 may be provided to penetrate at least a portion of the third insulating layer 610. The third redistribution patterns 615 may include a third via portion and a third wire portion, which may be connected to each other. For example, the third wire portion may be disposed on the third via portion. The third wire portion may be a horizontal interconnection in the third redistribution substrate 600. The third via portion, disposed in the third insulating layers 610, may vertically connect the third redistribution patterns 615 to each other. The third wire portion may be connected to the third via portion without any interface therebetween. The third wire portion of the third redistribution pattern 615 may be disposed on a top surface of the third insulating layer 610. The third via portion of the third redistribution pattern 615 may penetrate the third insulating layers 610 and may be connected to the third wire portion of a lower instance of the third redistribution pattern 615 thereunder. The third via portion may have a tapered structure that is extended in the third direction D3 and may have an increasing horizontal width in the third direction D3. For example, the third via portion may have an increasing width, as a distance to the second semiconductor chip 800 decreases. In an embodiment, the third redistribution patterns 615 may be formed of, or include copper (Cu).

Seed patterns may be disposed on bottom surfaces of the third redistribution patterns 615. For example, each of the seed patterns may be provided to cover the bottom and side surfaces of the third via portion of the third redistribution pattern 615 and the bottom surface of the third wire portion of the third redistribution pattern 615. The seed patterns may include a material different from the third redistribution patterns 615. For example, the seed patterns may include copper (Cu), titanium (Ti), or alloys thereof. In an embodiment, the third redistribution patterns 615 may further include a barrier layer preventing a material in the third redistribution patterns 615 from being diffused. The barrier layer may be formed of, or include titanium nitride (TiN) or tantalum nitride (TaN).

The third redistribution patterns 615 may include third redistribution pads 615a. For example, the third redistribution pads 615a may be portions of the third redistribution patterns 615 disposed at the uppermost level of the third redistribution substrate 600. The third redistribution pads 615a may have protruding top surfaces that extend to a height higher than the uppermost insulating layer of the third insulating layers 610.

Second under-bump patterns 620 may be provided on a bottom surface of the third redistribution substrate 600. The second under-bump patterns 620 may be spaced apart from each other in the first direction D1 and the second direction D2. The second under-bump patterns 620 may be electrically connected to the third redistribution patterns 615. For example, the second under-bump patterns 620 may be directly connected to the lowermost redistribution patterns of the third redistribution patterns 615. The second under-bump patterns 620 may be electrically connected to the third redistribution pads 615a through the third redistribution patterns 615. In an embodiment, the second under-bump patterns 620 may include copper (Cu).

Second connection terminals 850 may be provided on the third redistribution substrate 600. The second connection terminals 850 may be directly connected to the third redistribution pads 615a and may be electrically connected to the third redistribution pattern 615. The second connection terminals 850 may be spaced apart from each other in the first direction D1 and the second direction D2 to connect the third redistribution substrate 600 to the second semiconductor chip 800. In an embodiment, the second connection terminals 850 may include tin (Sn), bismuth (Bi), lead (Pb), or silver (Ag), or alloys thereof.

The second semiconductor chip 800 may be mounted on a top surface of the third redistribution substrate 600. The second semiconductor chip 800 may include chip pads disposed on a bottom surface of the second semiconductor chip 800. In an embodiment, the second semiconductor chip 800 may be a memory chip or a logic chip.

The second mold layer MD2 may be disposed on the top surface of the third redistribution substrate 600. The second mold layer MD2 may cover the second semiconductor chip 800, on the third redistribution substrate 600. For example, the second mold layer MD2 may be disposed on a top surface and a side surface of the second semiconductor chip 800. The second mold layer MD2 may further be disposed between the second semiconductor chip 800 and the top surface of the third redistribution substrate 600, surrounding the second connection terminals 850. In an embodiment, the second mold layer MD2 may include an epoxy molding compound.

Intermediate connection terminals 700 may be disposed between the first sub-semiconductor package 10 and the second sub-semiconductor package 20. The intermediate connection terminals 700 may electrically connect the first sub-semiconductor package 10 to the second sub-semiconductor package 20. For example, the intermediate connection terminals 700 may connect the second redistribution substrate 400 of the first sub-semiconductor package 10 to the third redistribution substrate 600 of the second sub-semiconductor package 20. The intermediate connection terminals 700 may be spaced apart from each other in the first direction D1 and the second direction D2. The intermediate connection terminals 700 may include a solder material. For example, the intermediate connection terminals 700 may include tin (Sn), bismuth (Bi), lead (Pb), or silver (Ag), or alloys thereof.

FIG. 2B is a sectional view illustrating a semiconductor package according to an embodiment of the inventive concept and corresponding to that of FIG. 2A. In the following description, an element previously described with reference to FIG. 1, FIG. 2A, and FIG. 3 may be identified by the same reference number without repeating, or by simplifying an overlapping description thereof.

Referring to FIG. 2B, the semiconductor package may include a third semiconductor chip 900 and a third mold layer MD3 on the second redistribution substrate 400. The third semiconductor chip 900 may be mounted on the second redistribution substrate 400. The third semiconductor chip 900 may include chip pads disposed on a bottom surface thereof. In an embodiment, the third semiconductor chip 900 may be a memory chip or a logic chip.

Third connection terminals 950 may be provided between the second redistribution substrate 400 and the third semiconductor chip 900. The third connection terminals 950 may be directly connected to the second redistribution pads 415a and may be electrically connected to the second redistribution pattern 415. Second connection terminals 450 may be spaced apart from each other in the first direction D1 and the second direction D2 and may connect the second redistribution substrate 400 to the third semiconductor chip 900. The third connection terminals 950 may include a solder material.

The third mold layer MD3 may cover the third semiconductor chip 900, on the second redistribution substrate 400. For example, the third redistribution substrate 600 and the intermediate connection terminals 700 may be omitted. The third mold layer MD3 may include an epoxy molding compound.

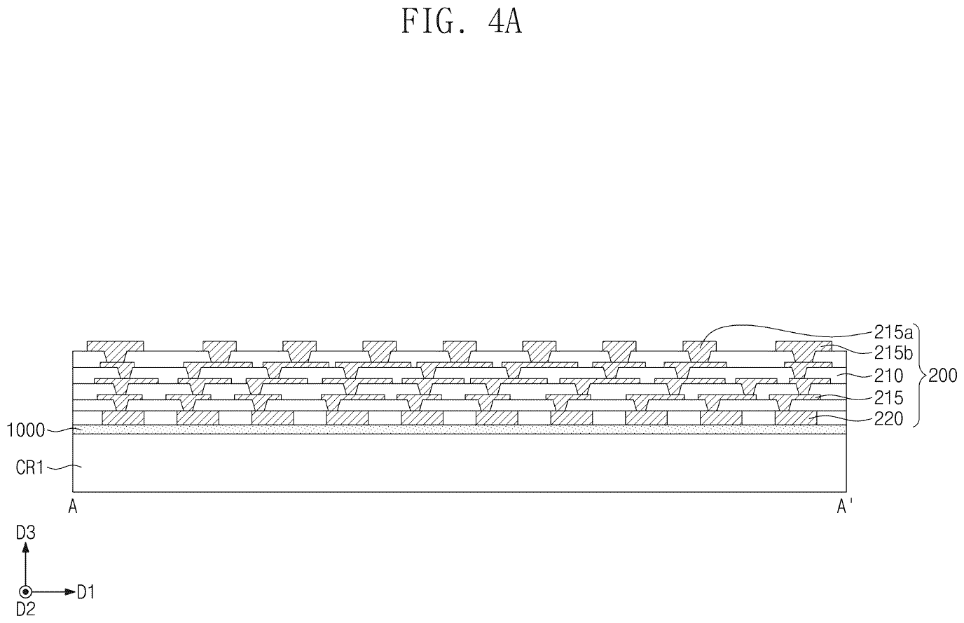

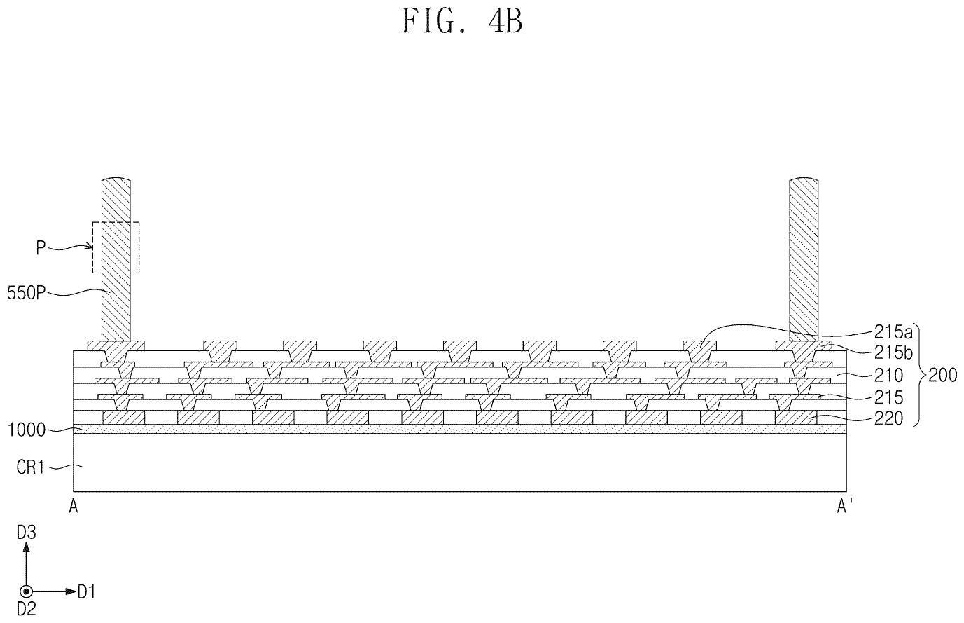

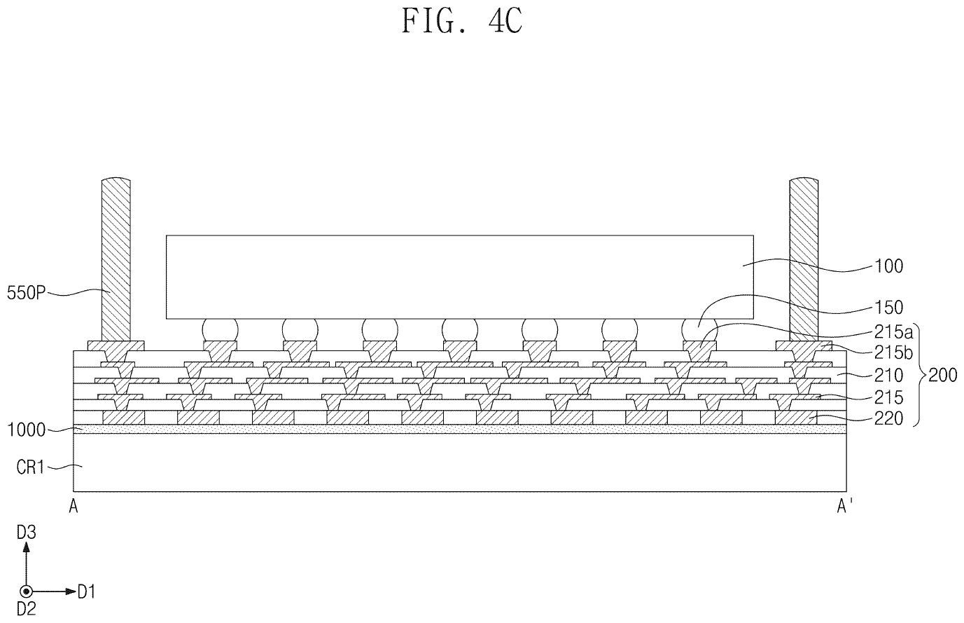

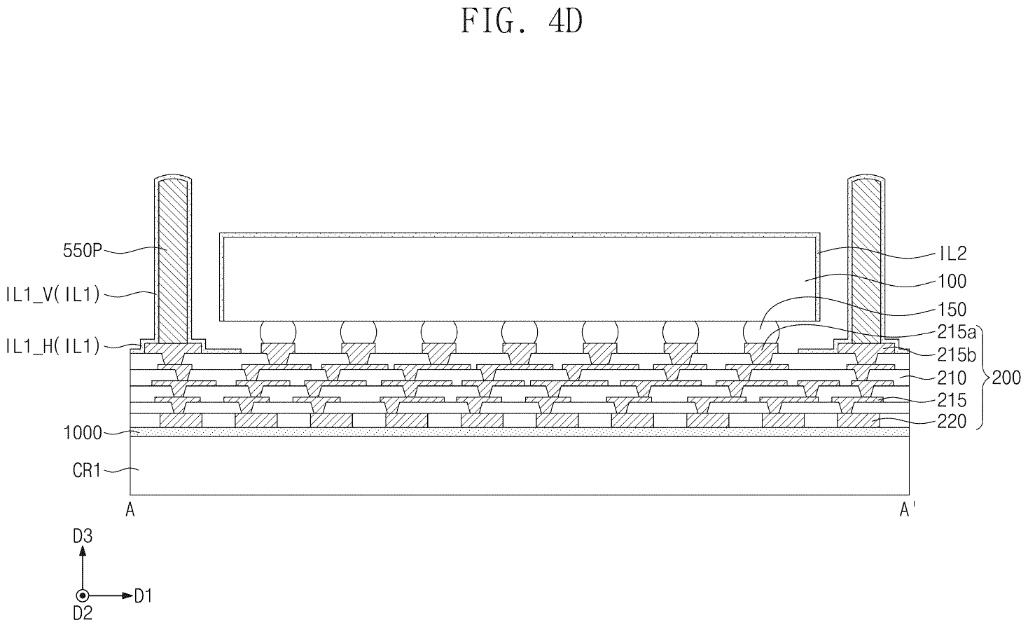

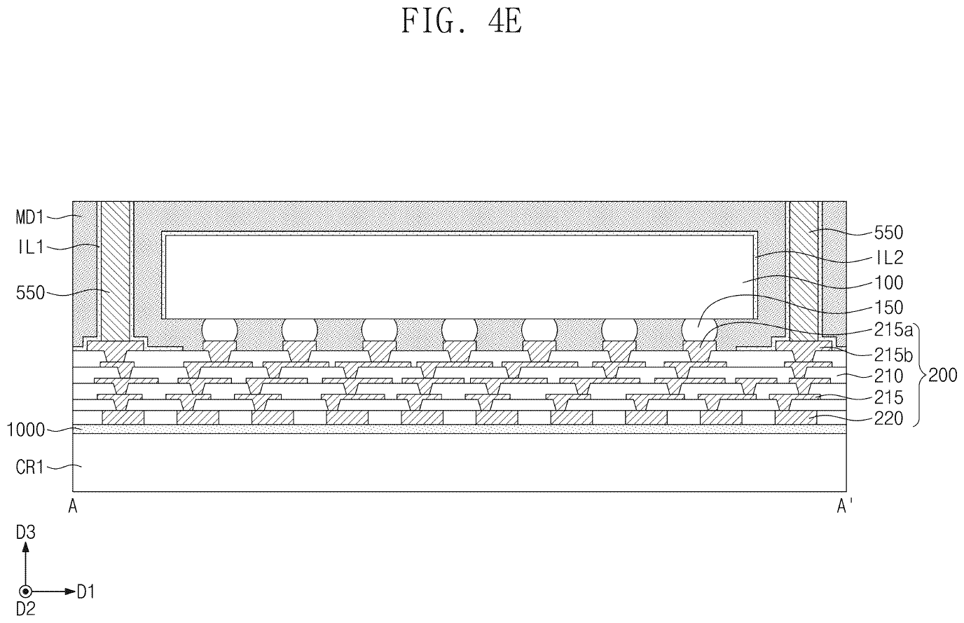

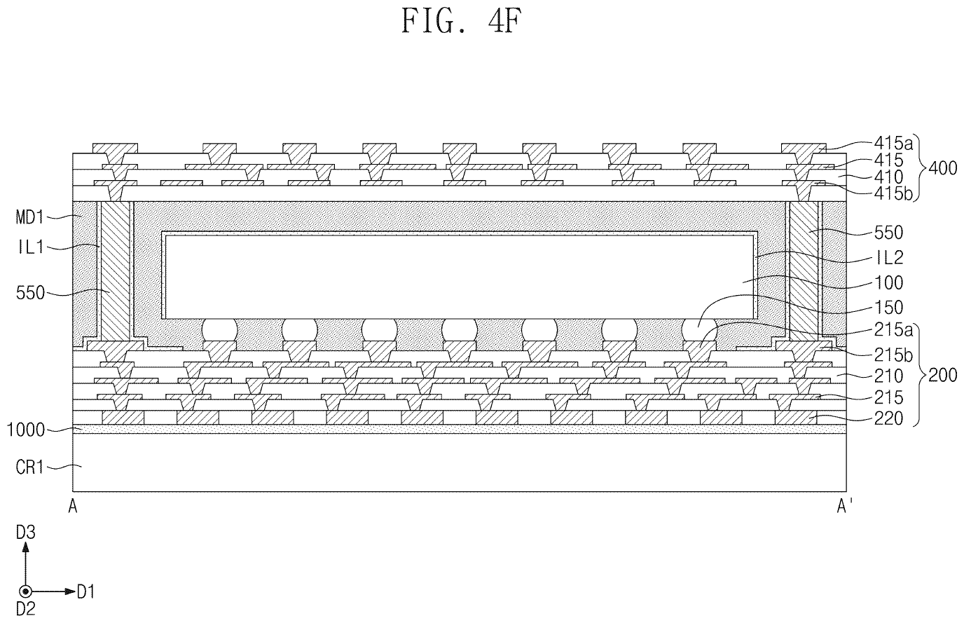

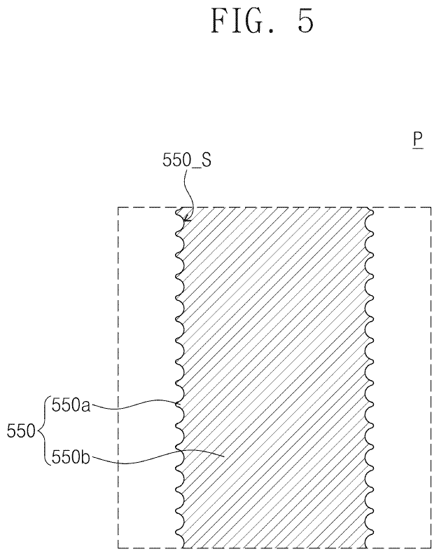

FIGS. 4A, 4B, 4C, 4D, 4E, and 4F and FIG. 5 are sectional views and an enlarged sectional view illustrating a method of fabricating a semiconductor package, according to an embodiment of the inventive concept. In detail, FIGS. 4A to 4F are sectional views corresponding to FIG. 2A, and FIG. 5 is an enlarged sectional view illustrating a portion ‘P’ of FIG. 4B.

Referring to FIG. 4A, a first carrier substrate CR1 and an adhesive member 1000 on the first carrier substrate CR1 may be provided. The first carrier substrate CR1 may be an insulating substrate, which includes glass or polymer, or a conductive substrate, which includes a metallic material. In an embodiment, the adhesive member 1000 may include an adhesive material and/or an adhesive tape.

The first redistribution substrate 200, which includes the first insulating layers 210, the first under-bump patterns 220, and the first redistribution patterns 215, may be attached to the adhesive member 1000. The formation of the first redistribution substrate 200 may include forming a lowermost insulating layer of the first insulating layers 210 on the adhesive member 1000 and the first carrier substrate CR1, forming the first under-bump patterns 220 to penetrate the first insulating layer 210, and additionally stacking the first insulating layers 210 on the lowermost insulating layer of the first insulating layers 210. The first redistribution patterns 215 may be formed following forming each insulating layer of the first insulating layers 210, wherein the first redistribution patterns 215 at least partially penetrate the first insulating layers 210.

The first insulating layers 210 may include an organic material (e.g., a photoimageable dielectric (PID) material). The formation of the first under-bump patterns 220 may include patterning the lowermost insulating layer of the first insulating layer 210 to form openings, forming a seed layer in the openings, and performing an electroplating process using the seed layer as an electrode to form a conductive pattern. The formation of the first redistribution pattern 215 may include patterning the first insulating layer 210 to form openings, forming a seed layer in the openings and on a top surface of the first insulating layer 210, forming a mask on the seed layer to define a space for a conductive pattern, performing an electroplating process using the seed layer as an electrode to form a conductive pattern, removing the mask, and patterning the seed layer using the conductive pattern as an etch mask. The first redistribution patterns 215 or the first redistribution pads 215a and 215b may be formed by repeating the afore-mentioned process.

Referring to FIG. 4B and FIG. 5, preliminary conductive posts 550p may be formed on the first redistribution substrate 200. The preliminary conductive posts 550p may be disposed on the first redistribution pads 215b. An adhesive element may be disposed between the preliminary conductive posts 550p and the first redistribution pads 215b. The adhesive element may be a conductive adhesive element.

A surface treatment process may be performed on the preliminary conductive posts 550p. In an embodiment, the surface treatment process may be performed through a plasma treatment process or a chemical treatment process. The surface treatment process may increase the surface roughness of the preliminary conductive posts 550p. In an embodiment, the surface roughness of the preliminary conductive posts 550p may range from about 0.1 μm to about 2 μm, in particular, from about 0.3 μm to about 1.3 μm. The surface treatment process may increase the surface roughness of the preliminary conductive posts 550p to have the protruding portions 550a formed on the surfaces of the preliminary conductive posts 550p.

Referring to FIG. 4C, the first semiconductor chip 100 may be disposed on the first redistribution substrate 200. The first semiconductor chip 100 may be electrically connected to the first redistribution substrate 200 through the first connection terminals 150. The first semiconductor chip 100 may be horizontally spaced apart from the preliminary conductive posts 550p.

Referring to FIG. 4D, the first interface layer IL1 and the second interface layer IL2 may be formed on the first redistribution substrate 200. In an embodiment, the first and second interface layers IL1 and IL2 may be formed through a chemical vapor deposition (CVD) method. In an embodiment, the first and second interface layers IL1 and IL2 may be formed simultaneously by a same process. The first interface layer IL1 may conformally cover the preliminary conductive posts 550p. The first interface layer IL1 may extend to at least partially cover the top surface of the first redistribution substrate 200. In an embodiment, the first interface layer IL1 may extend to a portion of an inner region disposed between the first semiconductor chip 100 and the first redistribution substrate 200.

The second interface layer IL2 may be formed on the top surface and side surfaces of the first semiconductor chip 100. In an embodiment, the second interface layer IL2 may not extend to a region under a bottom surface of the first semiconductor chip 100. The second interface layer IL2 may be spaced apart from the first interface layer IL1. The second interface layer IL2 may not be connected to the first interface layer IL1.

Referring to FIG. 4E, the first mold layer MD1 may be formed to cover the first redistribution substrate 200 and the first semiconductor chip 100. The first mold layer MD1 may be provided on the first redistribution substrate 200 and may fill an internal space between the first semiconductor chip 100 and the preliminary conductive posts 550p of FIG. 4D. The first mold layer MD1 may cover the first and second interface layers IL1 and IL2. The first mold layer MD1 may extend into the inner region disposed between the first semiconductor chip 100 and the first redistribution substrate 200.

The first mold layer MD1 and portion of the preliminary conductive posts 550p of FIG. 4D may be partially removed. In an embodiment, upper portions of the first mold layer MD1 and the preliminary conductive posts 550p may be removed through a grinding process. Since the preliminary conductive posts 550p of FIG. 4D are partially removed, they may be referred to as the conductive posts 550. The top surface of the first mold layer MD1 and the top surface of the first interface layer IL1 may be coplanar with the top surface of the conductive posts 550.

Referring to FIG. 4F, the second redistribution substrate 400 may be formed on the first mold layer MD1. The second redistribution substrate 400 may be formed on the top surface of the first interface layer IL1 and the top surface of the conductive posts 550. The formation of the second redistribution substrate 400 may include forming the second insulating layer 410 on the first mold layer MD1 and forming the second redistribution patterns 415 to at least partially penetrate the second insulating layers 410.

The second insulating layers 410 may include an organic material (e.g., a photoimageable dielectric (PID) material). The formation of the second redistribution pattern 415 may include patterning the second insulating layer 410 to form openings, forming a seed layer in the openings and on the top surface of the second insulating layer 410, forming a mask on the seed layer to define a space for a conductive pattern, forming a conductive pattern through an electroplating process using the seed layer as an electrode, removing the mask, and patterning the seed layer using the conductive pattern as an etch mask. The second redistribution patterns 415 or the second redistribution pads 415a may be formed by repeating the afore-mentioned process.

In the case where the first and second interface layers IL1 and IL2 are not formed, the first mold layer MD1 and the conductive posts 550 may be in direct contact with each other. A metal oxide layer (e.g., a copper oxide layer) may be formed on the side surfaces of the conductive posts 550 facing the first mold layer MD1, but in the case where the metal oxide layer is grown, the metal oxide layer may be delaminated from the side surfaces of the conductive posts 550 to form a void or crevice between the side surfaces of the conductive posts 550 and the metal oxide layer. In this case, a portion of the second insulating layer 410 may be formed in the void or crevice, and this may lead to a failure of the second redistribution substrate 400.

According to an embodiment of the inventive concept, the first interface layer IL1 may have a relatively strong adhesion strength, compared with the afore-described metal oxide layer, and the first mold layer MD1 and the conductive posts 550 may be strongly adhered to each other. Furthermore, the protruding portions 550a, which may be formed on the side surfaces 550_S of the conductive posts 550, may be robustly and mechanically coupled to the first interface layer IL1. For example, the protruding portions 550a and the first interface layer IL1 may inhibit or prevent the first mold layer MD1 from being delaminated from the conductive posts 550 (e.g., see FIG. 3). Accordingly, it may be possible to improve the reliability of the semiconductor package. For example, the adhesion of the first interface layer IL1 to the conductive posts 550 may inhibit or prevent the occurrence of a delamination of a structure including the first mold layer MD1, the first interface layer IL1 and the conductive posts 550, and may reduce a potential for cracks to form in the PID material during formation of the second insulating layers 410.

Referring back to FIG. 2A, the adhesive member 1000 and the first carrier substrate CR1 may be removed from the bottom surface of the first redistribution substrate 200. The first under-bump patterns 220 may be formed on the bottom surface of the first redistribution substrate 200.

The second sub-semiconductor package 20 may be disposed on the second redistribution substrate 400. The formation of the second sub-semiconductor package 20 may include forming the third redistribution substrate 600, mounting the second semiconductor chip 800 on the third redistribution substrate 600, and forming the second mold layer MD2 to cover the second semiconductor chip 800. The third redistribution substrate 600 may be formed by the same method as the method for forming the first redistribution substrate 200 described with reference to FIG. 4A.

According to an embodiment of the inventive concept, a semiconductor package may include a conductive post including protruding portions formed on a side surface of the conductive post, and an interface layer provided between a mold layer and the side surface of the conductive post having the protruding portions. The interface layer may be used to attach the mold layer to the conductive posts, and the protruding portions formed on the side surface of the conductive post may be robustly and mechanically connected to the interface layer. Accordingly, it may be possible to inhibit or prevent the mold layer from being delaminated from the conductive posts. For example, an air gap may not be formed between the mold layer and the conductive posts, and moreover, it may be possible to reduce a possibility of a failure, which may occur when an upper insulating layer on the mold layer is formed in the air gap. Thus, a semiconductor package with improved reliability may be provided.

While example embodiments of the inventive concept have been particularly shown and described, it will be understood by one of ordinary skill in the art that variations in form and detail may be made therein without departing from the spirit and scope of the attached claims.

What is claimed is:

1. A semiconductor package, comprising:
a first redistribution substrate;
a first semiconductor chip on the first redistribution substrate;
a conductive post on the first redistribution substrate and horizontally spaced apart from the first semiconductor chip, the conductive post having protruding portions formed on a side surface thereof;
a first mold layer disposed on the first redistribution substrate and a side surface of the first semiconductor chip; and
a first interface layer including a vertical portion between the first mold layer and the protruding portions of the conductive post and a horizontal portion extending from a lower end portion of the conductive post.

2. The semiconductor package of claim 1, wherein the first interface layer comprises a silicon-based insulating material.

3. The semiconductor package of claim 2, wherein the first interface layer further comprises copper oxide.

4. The semiconductor package of claim 1, wherein a thickness of the first interface layer ranges from about 1 micrometer (μm) to about 5 μm.

5. The semiconductor package of claim 1, further comprising a second interface layer covering a top surface of the first semiconductor chip and the side surface of the first semiconductor chip,
wherein the first interface layer and the second interface layer are spaced apart from each other.

6. The semiconductor package of claim 5, wherein the second interface layer comprises a first portion covering the top surface of the first semiconductor chip and a second portion covering the side surface of the first semiconductor chip, and
a thickness of the first portion is greater than or equal to a thickness of the second portion.

7. The semiconductor package of claim 1, wherein a surface roughness of the side surface of the conductive post defining the protruding portions ranges from about 0.1 micrometers (μm) to 2 μm.

8. The semiconductor package of claim 1, further comprising:
a second redistribution substrate on the first mold layer and electrically connected to the conductive post; and
a sub-semiconductor package on the second redistribution substrate,
wherein the sub-semiconductor package comprises:
a third redistribution substrate connected to the second redistribution substrate;
a second semiconductor chip mounted on the third redistribution substrate; and
a second mold layer covering the second semiconductor chip, on the third redistribution substrate.

9. The semiconductor package of claim 1, further comprising:
a second redistribution substrate on the first mold layer and electrically connected to the conductive post;
a third semiconductor chip mounted on the second redistribution substrate; and
a third mold layer covering the third semiconductor chip, on the second redistribution substrate.

10. The semiconductor package of claim 1, wherein a vertical portion of the first interface layer covers the side surface of the conductive post and the horizontal portion extends between the first mold layer and at least a portion of a top surface of the first redistribution substrate.

11. The semiconductor package of claim 1, wherein the horizontal portion of the first interface layer is overlapped with the first semiconductor chip, when viewed in a plan view.

12. A semiconductor package, comprising:
a first redistribution substrate;
a semiconductor chip on the first redistribution substrate;
a conductive post on the first redistribution substrate and horizontally spaced apart from the semiconductor chip;
a mold layer provided on the first redistribution substrate and on a side surface of the semiconductor chip; and
a first interface layer between the mold layer and a side surface of the conductive post,
wherein the side surface of the conductive post has a first surface roughness,
a top surface of the conductive post has a second surface roughness, and
the second surface roughness is smaller than the first surface roughness.

13. The semiconductor package of claim 12, wherein the first surface roughness ranges from about 0.1 micrometers (μm) to 2 about μm.

14. The semiconductor package of claim 12, wherein the second surface roughness ranges from about 0.001 micrometers (μm) to about 0.1 μm.

15. The semiconductor package of claim 12, wherein a thickness of the first interface layer ranges from about 1 μm to about 5 μm.

16. The semiconductor package of claim 12, wherein the first interface layer covers the side surface of the conductive post.

17. The semiconductor package of claim 12, further comprising a second interface layer disposed on a top surface and the side surface of the semiconductor chip,
wherein the first interface layer and the second interface layer are spaced apart from each other.

18. The semiconductor package of claim 17, wherein the second interface layer comprises a first portion covering the top surface of the semiconductor chip and a second portion covering the side surface of the semiconductor chip, and
a thickness of the first portion is greater than or equal to a thickness of the second portion.

19. A semiconductor package, comprising:
a first redistribution substrate including first insulating layers and first redistribution patterns, which at least partially penetrate the first insulating layers;
a semiconductor chip on the first redistribution substrate;
a conductive post on the first redistribution substrate and horizontally spaced apart from the semiconductor chip, a side surface of the conductive post defined by protruding portions;
a mold layer provided on the first redistribution substrate and a side surface of the semiconductor chip;
a first interface layer between the mold layer and the protruding portions of the conductive post and between the mold layer and at least a portion of a top surface of the first redistribution substrate;
a second redistribution substrate provided on the mold layer and electrically connected to the conductive post, the second redistribution substrate including second insulating layers and second redistribution patterns, which at least partially penetrate the second insulating layers; and
an outer coupling terminal on a bottom surface of the first redistribution substrate,
wherein the conductive post electrically connects the first redistribution patterns and the second redistribution patterns to each other.

20. The semiconductor package of claim 19, further comprising a second interface layer covering a top surface and the side surface of the semiconductor chip,
wherein the first interface layer and the second interface layer are spaced apart from each other.
